(19) United States
(12) Patent Application Publication
(10) Pub. No.: US 2004/0129214 A1
(43) Pub. Date: Jul. 8, 2004

(54) Method and apparatus for producing coated bores

(76) Inventors: Guenter Dannemann, Kornwestheim (DE); Helmut Schaefer, Kernen (DE); Walter Zwink, Freiberg (DE)

Correspondence Address: CROWELL & MORING LLP, INTELLECTUAL PROPERTY GROUP, P.O. BOX 14300, WASHINGTON, DC, 20044-4300, US

(21) Appl. No.: 10/471,209

(22) PCT Filed: Jan. 31, 2002
(86) PCT No.: PCT/EP02/00982

(30) Foreign Application Priority Data
Mar. 10, 2001 (DE) 101 11 569.5

(51) Int. Cl. C23C 16/00; B05D 7/22; B05D 1/08

(52) U.S. Cl. 118/715; 427/230; 427/446

(57) ABSTRACT

The invention relates to a method and a device for producing coated holes, in which, after the hole is formed, the hole wall is plasma-sprayed with a coating material. In order to enable, in a relatively simple manner, the coating of the hole wall to be sufficiently durable with respect to mechanical loads, it is proposed that the hole wall be subjected to flow-turning machining.

The invention relates to a method for producing coated holes according to the precharacterizing clause of patent claim 1 and to a device for carrying out the same according to the precharacterizing clause of patent claim 7.

In conventional methods and devices for coating holes, the walls of which are plasma-sprayed in order to make them wear-resistant and at the same time to provide them with good sliding qualities, the adhesive strength, which is too low as a consequence of the uniform layering, means that, in practical use of the layer in contact with a tribology partner, an early overloading of the layer occurs, causing it to flake off or form cracks. This may result in complete failure of the interacting functional components concerned.

A method of the generic type and a device of the generic type are disclosed in DE 198 47 608 A1. In this case, a layer which is sprayed onto a cylinder hole wall and consists of melted, powdery additives is aftertreated in such a manner that the sensitivity of the layer to wear, which is caused by the high porosity, is reduced or avoided. In this case, the porous layer is compacted by rolling.

In the same manner, U.S. Pat. No. 4,976,995 discusses the compaction of layers with rolls during the coating process, the layers being applied on the outside of a substrate.

U.S. Pat. No. 1,472,155 makes provision for plasma spraying to be used to apply a layer onto a steel roller. This layer is flow-turned, this treatment being intended to obtain a desired shaped profile for the layer. A shaping element which can be rotated about an axis is used for this purpose.

EP 0716 158 A1 describes the production of an engine block with coated holes, the coating being undertaken by plasma spraying.

The invention is based on the object of developing a method of the generic type and a device of the generic type to the effect that the coating of the hole wall can be made sufficiently durable with respect to mechanical loads in a relatively simple manner.

The object is achieved according to the invention by the features of patent claim 1 in respect of the method and by the features of patent claim 7 in respect of the device.

The machining of the hole by means of flow turning has the effect of leveling out even slight unevenesses in the wall—which do not include the roughness of the material of the hole wall—as a result of which the coating material can stick substantially better and more homogeneously in the surface of the wall, so that the adhesive strength of the layer is considerably increased, which results in increased durability of the coating with respect to mechanical loads. The uniformity of the layer thickness makes a further contribution to the durability. Said uniformity firstly prevents harmful shearing stresses which are caused at sink marks—i.e. points of reduced layer thickness—by the tension or compression of the friction partner against the layer. Secondly, this avoids layer sections being detached due to the contact of the friction partner with excess accumulations of layer material, which arise in the clear opening of the hole, and therefore impermissibly high spot-like mechanical stresses at these points. The machining takes place in a rotating manner with a simultaneously axial stroke of the tool along the hole which is to be smoothed.

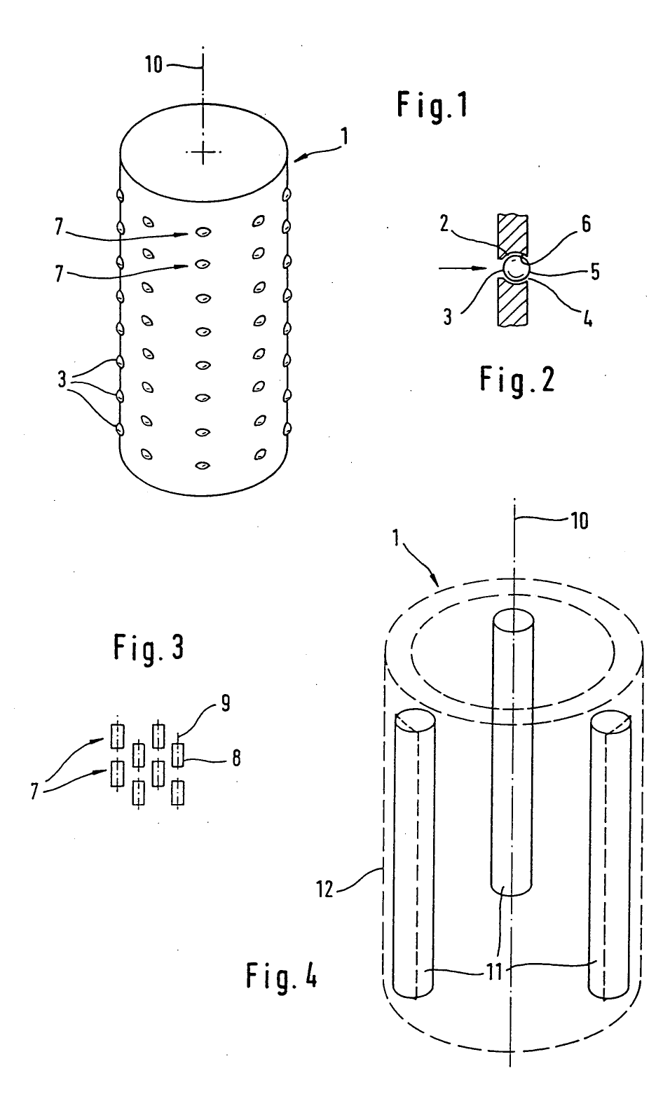

The device according to the invention comprises a tool (not shown in the exemplary embodiments) for forming a hole, for example a casting device, a milling cutter or a turning device, and a plasma-spraying device of a customary type. Furthermore, the device contains a flow-turning tool which is composed of a motor-operated machining spindle and a machining head 1 which is fastened to the latter on the end side, as illustrated in FIG. 1.

The machining head 1 is designed as a cylindrical cage which is matched in its dimensions to the hole which is to be machined and which has on its circumference a multiplicity of cavities 2 which are open in the radial direction of the cage (FIG. 2). Rolling elements in the form of balls 3 which can be deployed radially and the curvature of which is matched to the hole wall are held in the cavities 2 in a manner such that they can float freely. The balls 3 are acted upon fluidically here via a line system, which is connected to the cavities 2, when the machining head 1, when being used, is lowered into the hole. In this case, the balls 3 are deposited hydraulically according to the direction of the arrow and are therefore deployed in the use position for the machining. For this purpose, the cavities 2 are designed in such a manner that the balls 3 can penetrate the openings 4 of the cavities 2 toward the outside with a spherical section 5 in each case. In the use position, the balls 3 are pressed against the cavity wall 6, which surrounds the openings 4, specifically in such a manner that the balls 3—lubricated by the hydraulic fluid—can still rotate in every direction without obstruction. The hole wall can now be acted upon mechanically by the flow-turning tool. The machining of the hole wall with the machining head 1 equipped with the balls 3 is economical in terms of the method and requires little outlay in terms of the apparatus. The use of balls 3 affords the advantage that the forming forces acting specifically on the hole wall are locally relatively high, but again low, as seen in terms of the loading of the entire surface. Effective machining of the hole wall is therefore made possible without this leading to formation of cracks on the latter. It is advantageous to form the balls 3 from ceramic, for example from SiN, since this material is distinguished by a high hardness, high wear resistance and with little tendency to adhere to the metallic wall material, which consists, if appropriate, of aluminum. The balls 3, which have a uniform diameter of 5 mm to 20 mm, are arranged on the machining head 1 in a plurality of rows 7 which lie next to one another and run in the circumferential direction of the machining head 1, the rows 7 being offset with respect to one another. In this case, sympathetic vibrations, which would cause damage to the tool and damage to the hole wall, during the machining of the hole wall are avoided by reciprocal elimination of the natural vibrations of the individual balls 3. As an alternative to the balls 3, a multiplicity of short, barrel-shaped rolls 8, the longitudinal axes 9 of which lie parallel to the longitudinal axis 10 of the machining spindle (FIG. 3) and which are arranged offset on the circumference of the machining head 1, may also be used as rolling elements. Furthermore, according to FIG. 4 elongate tumbling rolls 11 are also conceivable as rolling elements, said rolls extending in each case over the longitudinal extent of the machining head 1 and being held on the latter in such a manner that they protrude with a circumferential section through the casing surface 12 of the head 1. The deployment of the rolling elements, which—as described above—takes place fluidically, may also be brought about mechanically by means of an expanding-cone arbor. In one advantageous refinement of the invention, the machining spindle of the flow-turning tool is formed by that of a honing machine. Therefore, as the necessity arises, a tool can be saved by simply exchanging the machining head 1 for the honing stone. Advantageously added to this is the fact that the honing machine uses a known technique, the parameters of which, such as turning speed, stroke speed and the hydraulic and electrical provision of the rolling elements, can be reliably controlled.

If the hole wall is used as a cylinder face of an internal combustion engine consisting of an aluminum die casting, pores are produced in this wall material at a depth of up to 0.3 mm, individually even up to 1.2 mm, which results in a nonuniform layer thickness—as seen over the cylinder face—during the coating by means of plasma spraying. Also, the pores reduce the adhesive strength of the layer. It is therefore advantageously appropriate, in the given application, to allow the flow-turning machining to take place before the plasma spraying, since this enables the pores to be “kneaded shut” in advance by the rolling elements, which act upon the hole wall with contact pressure, and the cylinder face is therefore considerably more even. The adhesive strength of the layer on the hole wall and the sliding qualities of the cylinder face for the piston ring of the cylinder piston are therefore increased equally. Furthermore, the layer can be applied completely homogeneously in its thickness, which has a considerable positive effect on the sliding qualities. In order to even out the layer thickness, flow turning is also possible after the plasma spraying. Since the pores form an oil-retaining volume for engine oil, the closing of the pores by means of the flow turning substantially reduces the oil consumption during operation of the engine and therefore the pollutant emission during combustion in the cylinder. Sufficient oil still remains in the surface roughness of the cylinder face to lubricate the cylinder piston. Furthermore, surface bonding is achieved by the flow turning, which increases the strength of the light metal die casting, which, as mentioned, can consist of aluminum or of magnesium, and therefore of the cylinder slideway.

If the hole wall is used as a bearing face of a bearing seat of a crankshaft or as an inner face of a connecting rod eye of an internal combustion engine, it is expedient to begin the flow-turning machining after the plasma spraying. In this case, the applied layer, which has approximately a thickness of 200 micrometers in the sliding bearing, is evened out, which improves the sliding qualities of the hole wall and at the same time increases the connection of the layer to the hole wall owing to the layer pressing against the hole wall under the action of the rolling elements following the roll-bonding to increase the adhesive strength. The application of a layer which is precision-formed in this manner enables the bearing shells to be replaced in a manner which saves on components and is optimized in terms of manufacturing tolerances.

For all spheres of application of flow turning, a measuring device, which is held by the device and operates, for example, acoustically, visually or by contact, can be integrated into the flow-turning device and, during the process of producing the hole, measures the diameter of the hole stepwise or continuously and, when the predetermined desired diameter is reached, causes the flow-turning tool to become inoperative or to be switched off. A signal processor of the device comes into effect in this case, said processor detecting a control signal which is output by the measuring device and feeds it to a controller of the flow-turning tool in order to end the flow-turning process.

The variability of the layer thickness in the μ region by the flow turning enables the previous variety of connecting-rod basic bodies and therefore of connecting-rod classes to be decisively minimized, since bearing pairings requiring very different micrometer coordinations with the crankshaft are rendered superfluous. In principle, other spheres of application to the method and device according to the invention are also conceivable, for example in transmission shafts and gearwheels in the axle mechanism.

1. A method for producing coated holes, in which, after the hole is formed, the hole wall is plasma-sprayed with a coating material, characterized in that the hole wall is subjected to flow-turning machining, unevenesses in the hole wall being leveled out.

2. The method as claimed in claim 1, characterized in that the flow-turning machining takes place after the plasma spraying.

3. The method as claimed in claim 1, characterized in that in the case of large-pored wall materials, the flow-turning machining takes place before the plasma spraying.

4. The method as claimed in one of claims 1 to 3, characterized in that a cylinder face of an internal combustion engine is used as the hole wall.

5. The method as claimed in one of claims 1 to 3, characterized in that the bearing face of a bearing seat of a crankshaft or the inner face of a connecting rod eye of an internal combustion engine is used as the hole wall.

6. The method as claimed in one of claims 1 to 5, characterized in that the diameter of the hole is measured stepwise or continuously during the flow-turning machining, and in that when a predetermined desired diameter is reached, the measuring device outputs a control signal which ends the flow-turning machining.

7. A device for producing coated holes with a tool for forming the hole, with a plasma-spraying device performing the coating and having a flow-turning tool which can be used to act upon the hole wall, characterized in that the flow-turning tool is composed of a motor-operated machining spindle and a machining head (1) which is fastened to the latter on the end side.

8. The device as claimed in claim 7, characterized in that the machining head (1) bears rolling elements which can be deployed radially and the curvature of which is matched to the hole wall.

9. The device as claimed in claim 8, characterized in that the rolling elements can be deployed hydraulically.

10. The device as claimed in claim 8, characterized in that the rolling elements can be deployed by means of an expanding-cone arbor.

11. The device as claimed in one of claims 8 to 10, characterized in that the rolling elements comprise a multiplicity of short, barrel-shaped rolls (8), the longitudinal axes (9) of which lie parallel to the longitudinal axis (10) of the machining spindle.

12. The device as claimed in one of claims 8 to 10, characterized in that the rolling elements are balls (3) which are held on the machining head (1) in a manner such that they can float freely.

13. The device as claimed in claim 12, characterized in that the balls (3) are held in radially open cavities (2) of a cylindrical cage which forms the machining head (1), it being possible for the openings (4) of the cavities (2) to be penetrated by a spherical section (5) of the ball (3) in each case.

14. The device as claimed in one of claims 8 to 13, characterized in that the rolling elements consist of ceramic.

15. The device as claimed in one of claims 8 to 14, characterized in that the rolling elements are arranged on the machining head (1) in a number of rows (7) which lie next to one another and run in the circumferential direction of the machining head (1), the rows (7) being offset with respect to one another.

16. The device as claimed in one of claims 8 to 10, characterized in that the rolling elements are elongate tumbling rolls (11) which extend in each case over the longitudinal extent of the machining head (1).

17. The device as claimed in one of claims 7 to 16, characterized in that the machining head (1) of the flow-turning tool is arranged instead of a honing stone on the machining spindle of a honing machine.

18. The device as claimed in one of claims 7 to 17, characterized in that the device contains a signal-emitting measuring device which can be used to detect the hole diameter by contact or visually, and comprises a signal processing which detects a control signal which is output by the measuring device when a predetermined hole diameter is reached and feeds it to a controller of the flow-turning tool in order to end the flow-turning process.
